(19) United States
(12) Patent Application Publication
(10) Pub. No.: US 2011/0012635 A1
(43) Pub. Date: Jan. 20, 2011

(54) WET HIGH POTENTIAL QUALIFICATION TOOL FOR SOLAR CELL FABRICATION

(75) Inventors: Danny Cam Lu, San Francisco, CA (US); Michael Marriott, Morgan Hill, CA (US); Jeffrey S. Sullivan, Castro Valley, CA (US); Sanoj James, Bangalore (IN); Balasundaram Chidambaranathan, Bangalore (IN)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/628,851

(22) Filed: Dec. 1, 2009

(30) Foreign Application Priority Data
Jul. 15, 2009 (IN) 1685/CHE/2009

(51) Int. Cl. G01R 31/02

(52) U.S. Cl. 324/757.03; 136/290; 134/95.2

(57) ABSTRACT

Embodiments of the invention generally provide methods and an apparatus for processing and qualifying a formed photovoltaic device to assure that the formed photovoltaic device meets desired quality and industry electrical standards. Embodiments of the present invention may also provide a photovoltaic device, or solar cell device, production line that is adapted to form a thin film solar cell device by accepting an unprocessed substrate and performing multiple deposition, material removal, cleaning, bonding, and testing steps to form a complete functional and tested solar cell device. The solar cell device production line, or system, is generally an arrangement of processing modules and automation equipment used to form solar cell devices that are interconnected by automated material handling system. In one embodiment, the system is a fully automated solar cell production line that is designed to reduce and/or remove the need for human interaction and/or labor intensive processing steps to improve the device reliability, process repeatability, and the solar cell formation process cost of ownership (CoO).

### FIELD OF INVENTION

Embodiments of the present invention generally relate to apparatus and processes for testing and qualifying a photovoltaic device in a production line.

### BACKGROUND

Photovoltaic (PV) devices, or solar cells, are devices which convert sunlight into direct current (DC) electrical power. Typical thin film PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers.

With traditional energy source prices on the rise, there is a need for a low cost way of producing electricity using a low cost solar cell device. Conventional solar cell manufacturing processes are highly labor intensive and have numerous interruptions that can affect the production line throughput, solar cell cost, and device yield. For instance, conventional quality inspection of solar cell devices is typically either only conducted on fully formed solar cell devices via performance testing or on partially formed solar cell devices that are manually removed from the production line and inspected. Neither inspection scheme provides metrology data to assure the quality of the solar cell devices and diagnose or tune production line processes during manufacturing of the solar cell devices.

Therefore, there is a need for an automated test apparatus for photovoltaic substrates that provides for automated testing in a compact, easily maintained unit for use in high-volume manufacturing facilities.

### SUMMARY

Embodiments described herein provide an apparatus for processing a solar cell substrate comprising a test apparatus, which comprises a test fluid enclosure, an electrical sensor disposed in the test fluid enclosure, and a substrate support having a frame for handling a substrate, a connection pod for making electrical connection with connectors disposed within the substrate, and a motion assembly for positioning the substrate, and a cleaning apparatus, which comprises a rinse station configured to spray a rinsing fluid on two surfaces of the substrate and a gas knife for removing liquid from the substrate.

Other embodiments provide a test apparatus for a solar cell manufacturing line comprising an entry conveyor for transporting solar cell substrates from the solar cell manufacturing line to the test apparatus, an attachment device for attaching a junction box to the solar cell substrate, a solar simulator configured to flash solar spectrum radiation and sense electric current produced by the solar cell substrate, and a high potential tester comprising a test fluid enclosure for containing an electrolyte test fluid, an electrical sensor disposed in the test fluid enclosure, a substrate handler configured to engage with the substrate and dispose the substrate in the electrolyte test fluid, the substrate handler comprising a connection pod configured to make electrical connection with the junction box, a power supply connected to the connection pod and the electrical sensor, a rinse dry station, and an exit conveyor for delivering substrates from the test apparatus to the solar cell manufacturing line.

Other embodiments provide a method of processing a solar cell substrate comprising disposing the substrate in a test fluid, applying a voltage to contacts disposed within the substrate, sensing electric current emerging from an edge of the substrate into the test fluid using a current sensor immersed in the test fluid, removing the substrate from the test fluid, rinsing the test fluid from the substrate, and drying the substrate using a gas knife.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a wet high potential test apparatus according to one embodiment.

FIG. 2 is a schematic side view of a test apparatus according to one embodiment.

FIG. 3A is a plan view of a wet high potential test apparatus in single-substrate test mode according to another aspect.

FIG. 3B is a plan view of the wet high potential test apparatus of FIG. 3A in dual-substrate test mode.

FIG. 3C is a top view of a substrate connected to the apparatus of FIG. 3A or 3B.

FIG. 4 is a flow diagram summarizing a test method for a solar cell substrate according to one aspect.

FIG. 5A is a schematic side-view of a wet high potential test apparatus according to another embodiment.

FIG. 5B is a top view of the apparatus of FIG. 5A.

FIG. 6 is a flow diagram summarizing a method according to another embodiment.

FIG. 7A is a schematic side view of a wet high potential test apparatus according to another embodiment.

FIG. 7B is a plan view of a wet high potential test facility according to another embodiment.

FIG. 8 is a schematic plan view of a wet high potential test facility according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally provide methods and apparatus for processing and qualifying a formed photovoltaic device to assure that the formed photovoltaic device meets desired quality and industry electrical standards. Embodiments of the present invention may also provide a photovoltaic device, or solar cell device, production line that is adapted to form a thin film solar cell device by accepting an unprocessed substrate and performing multiple deposition, material removal, cleaning, bonding, and testing steps to form a complete functional and tested solar cell device. The solar cell device production line, or system, is generally an arrangement of processing modules and automation equipment used to form solar cell devices that are interconnected by automated material handling system. In one embodiment, the system is a fully automated solar cell production line that is designed to reduce and/or remove the need for human interaction and/or labor intensive processing steps to improve the device reliability, process repeatability, and the solar cell formation process cost of ownership (CoO).

One set of embodiments provides an apparatus that is used to test and qualify the electrical isolation of a photovoltaic device that is formed on a substrate and encapsulated within a composite solar cell structure from the external environment. The apparatus, or electrical testing module, generally comprises a substrate receiving region, a wet electrical isolation testing region, a substrate cleaning region, and an automation control system. During processing the electrical testing module is configured to received a fully formed solar cell device, transfer the formed solar cell device to the testing region in an automated fashion, perform one or more electrical qualification tests, transfer the formed solar cell device to the substrate cleaning region in an automated fashion, and perform one or more cleaning processes on the formed solar cell device. In one embodiment, the one or more electrical qualification tests comprises a wet high potential qualification test that is used to assure that the formed solar cell device meets desired quality and industry electrical isolation standards.

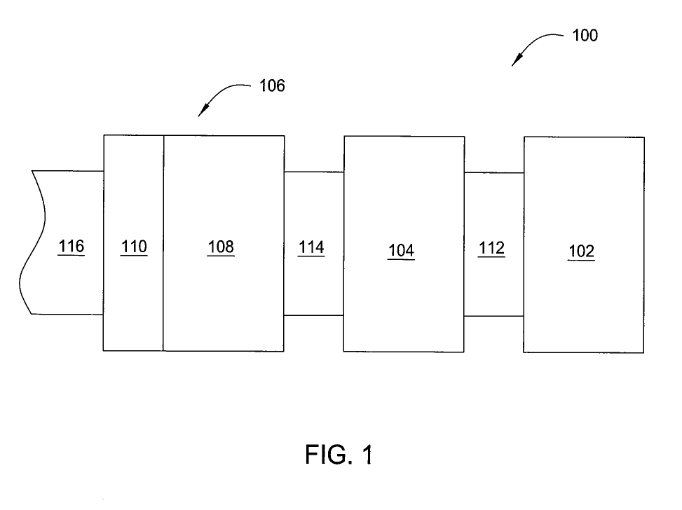

An apparatus for conducting a wet high potential test of a solar cell device generally comprises a tank for contacting the solar cell device with a test fluid, which may comprise a surfactant solution, possibly including water and/or other aqueous media. FIG. 1 is a plan view of a portion of a solar cell production line, or apparatus 100, according to one embodiment of the invention. In one embodiment, the apparatus may be part of the back-end-of-the-line (BEOL) in which solar cells positioned within this part of the production line are tested to assure compliance with various quality and industry electrical standards. In one embodiment, the apparatus 100 comprises an attachment apparatus 102 for attaching a junction box to a solar cell substrate, a solar simulation apparatus 104 for testing response of a solar substrate to solar radiation, and a wet high potential test apparatus 106 for testing the dielectric resistance of a solar cell substrate. Conveyors 112, 114 and 116 are shown interfacing the various test units together in a fabrication apparatus. The wet high potential test apparatus 106 comprises a test portion 108 and a cleaning portion 110.

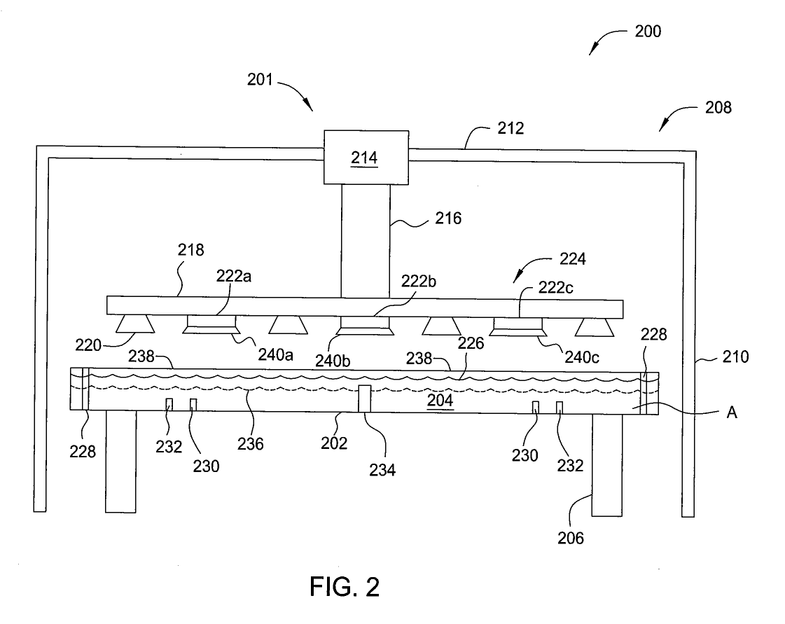

FIG. 2 is a schematic side view of a test apparatus 200 found in the wet high potential test apparatus 106 according to one embodiment. The test apparatus 200 generally corresponds to the test portion 108 of FIG. 1. The test apparatus 200 comprises a test table 202, an automation assembly 201, and a support 224. The test table 202 comprises one or more legs 206 and a tank 204 for holding a test fluid “A”. The test fluid A will generally be a conductive fluid, such as water, optionally with a surfactant or electrolyte to enhance conductivity of the test fluid A. The tank 204 will generally be made of an insulating material with structural strength to contain the test fluid A and to support sensors disposed in the tank 204, as discussed further below. In one embodiment, the tank 204 is made of a plastic or polymer material. The tank 204 comprises a divider 234 that extends from the floor of the tank 204 to a height less than the height of the tank side wall. The divider 234 enables operating the tank 204 as two separate tanks by lowering the level of the test fluid A from a level higher than the height of the divider 234, such as level 226, to a level lower than the height of the divider 234, such as level 236.

In one embodiment, the automation assembly 201 comprises a gantry 208, motion assembly 214 and a plurality of connection pods 222a-222c that are used to position one or more solar cell substrates with respect to the test tank 204 and other components of the apparatus 100 of FIG. 1, and to form an electrical connection with connectors disposed in the solar cell substrates so that the wet high potential testing process can be performed on the substrates in an automated fashion. The connection pods 222a-222c support independent connections to one or more solar cell substrates. For example, a single substrate may be connected to any of the connection pod 222a-222c. A large substrate covering most of the area of the tank may be connected to the connection pod 222b at a central location of the tank. If two substrates are to be processed simultaneously, one may be connected to the connection pod 222a at the same time the other is connected to the connection pod 222c. The two substrates may be processed simultaneously and independently, as discussed in further detail below.

Each of the connection pods 222a-222c has a seal 240a-240c, respectively, that seals the electrical connection between the connection pod 222 and the substrate. In one embodiment, connectors disposed in the substrate are collected in a junction box near the center of the substrate for easy access. A connection pod 222 may connect by mating with connectors in a junction box. The seal 240 couples to the connection pod 222 and the junction box to prevent test fluid from entering the junction box or the connection pod when the substrate is exposed to the test fluid.

In another embodiment, each of the connection pods 222 has a plurality of seals that mate with the connectors in the connection pod and the connectors in the junction box to seal each individual connection made between the test apparatus and the substrate. In another embodiment, the plurality of seals may include connector seals as well as a junction box seal of the type described above.

The support 224 comprises one or more shafts, rods, or connectors 216 that couple the support 224 to a motion assembly 214. The motion assembly generally raises and lowers the support 224 to position a substrate in a test position or to transport the substrate into and out of the test apparatus 200. The support 224 also comprises one or more cross members 218 that engage with and hold a substrate using attachment vectors 220. The attachment vectors 220 may be suction cups for certain substrates. The attachment vectors 220 generally contact a major surface of the substrate to hold it in place for testing. In one embodiment, attachment of the substrate to the attachment vectors 220 is maintained by vacuum. In another embodiment, an attachment vector may comprise opposable members that contact opposite major surfaces of the substrate. In yet another embodiment, a substrate may be held in place and manipulated by edge grippers, which may contact the edge portions or corner portions of a substrate. Each of the connection pods 222, which are connected to the support 224, has two or more probes that are generally used to probe the positive and negative leads of the solar cell. Each connection pod 222 is configured to deliver voltage to its connected substrate during a test procedure. In one embodiment, the probes and connectors within a connection pod 222 engage with connectors disposed within the junction box disposed on a substrate, establishing electrical connection therewith.

The tank 204 comprises a plurality of sensors 228, 230, and 232. A level sensor 228 indicates the liquid level in the tank 204 and is used to ensure sufficient test fluid A in the tank 204 for testing. A temperature sensor 230 is used to control the temperature of the test fluid A to ensure the test fluid A has adequate conductivity. A conductivity sensor 232 is used to control the concentration of electrolyte in the test fluid A. Two sets of sensors are provided to enable operating two test portions of the tank 204 by lowering the liquid level to a height below the height of the divider 234. In operation, test fluid medium or solvent is added if a level sensor indicates the level of test fluid A in the tank 204 is too low. Electrolyte is added to the test fluid A if a conductivity sensor 232 indicates the conductivity of the test fluid A is too low. The test fluid A is warmed or cooled in response to indication from the temperature sensor 230 that the test fluid temperature is out of a specified range.

In one embodiment, each test portion of the tank 204 has a drain (not shown) that operates independent of the other test portion to allow selective control of the test fluid level of each test portion. When the tank 204 is operated as a single test facility, with test fluid level 226 above the height of the divider 234, one or both drains may be used to control the test fluid level. When the tank 204 is operated as two or more test portions, each drain is used to control the liquid level in its test portion.

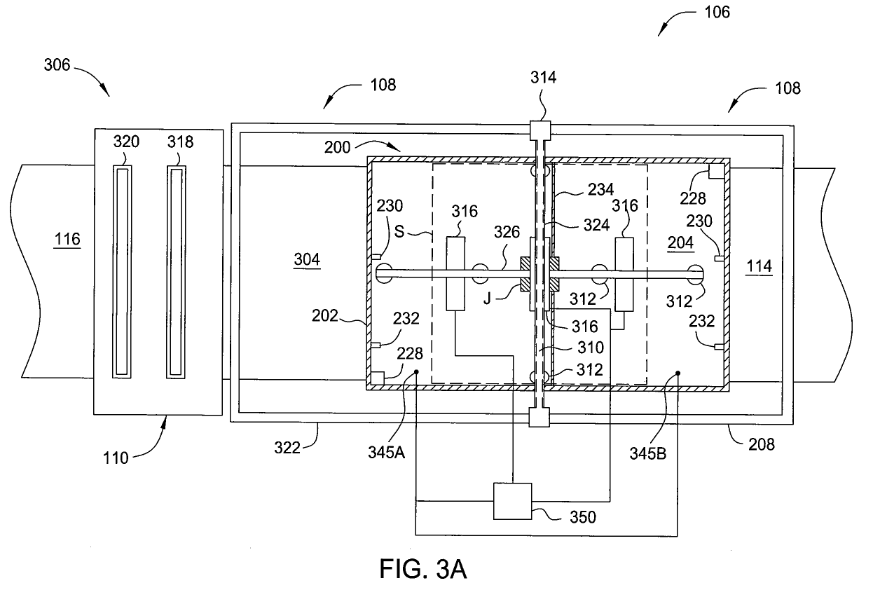

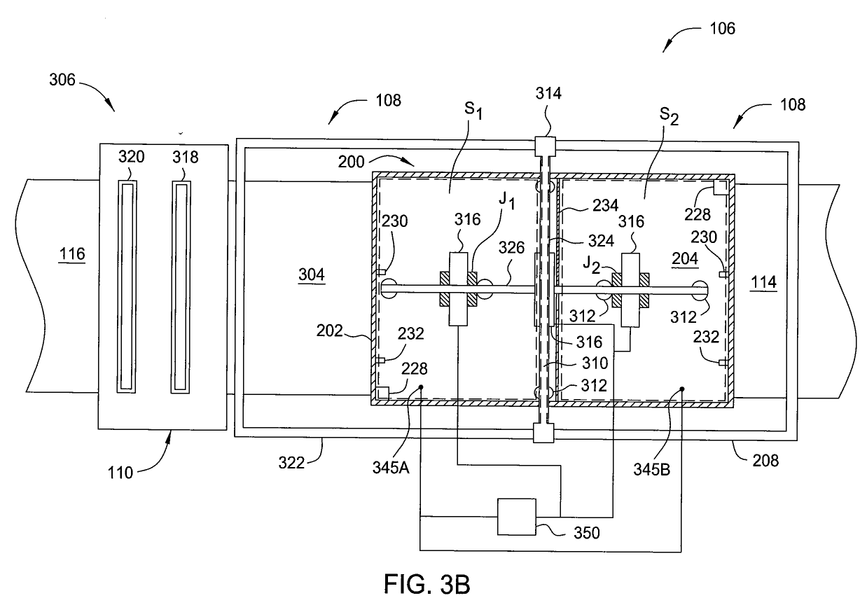

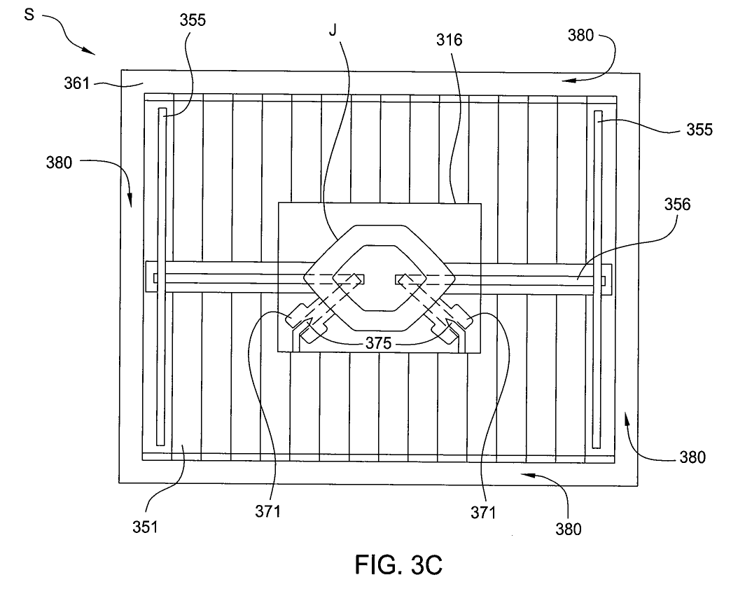

FIG. 3A is a plan view of a wet high potential test apparatus 106 according to another aspect. The wet high potential test apparatus 106 comprises a test tank 204, a conveyor 304, a rinse and dry station 306, and the gantry 208. The gantry 208, which is disposed in the automation assembly 201, is configured to move solar cell substrates through the various processes performed in the apparatus 100. The gantry 208 generally comprises a support frame 322 and a cross-member 324 that travels along the support frame 322 of gantry 208 by operation of translators 314 coupled to the gantry 208. The cross-member 324 supports one or more substrate handling members 326 with attachment vectors 312 for attaching to the substrate. The one or more substrate handling members 326 also comprise a plurality of connection pods 316 for making electrical connection with the substrate.

Substrates may be supported by any convenient configuration of support members. In one embodiment, the cross-member 324 may be replaced by a carriage comprising a plurality of cross-members, each coupled to the gantry 208 by a set of translators 314. Additionally, more than one substrate handling member 326 may be provided. In other embodiments, curved or angled members may also be provided to connect the various support members, improving the rigidity of the support structure. Providing more support members may improve handling of substrates in some embodiments by constraining undesirable motion vectors such as flexing and wobbling.

The test tank 204 comprises a first electrode 345A disposed in the test tank 204. The first electrode 345A is configured to detect current emerging from the solar cell substrate “S” disposed in the test fluid “A”. A second electrode 345B, similar to the first electrode, may be disposed in the test tank 204 as well. The second electrode 345B provides a redundant current reading as a way to check the accuracy of current readings from both electrodes 345. As is described further below, the second electrode 345B also allows operating the test tank 204 as two separate test stations. A power supply 350 is connected to the connection pods 316 to deliver power to the junction box “J” of the substrate S. The electrodes 345 are also connected to the power supply 350 to complete the test circuit. In one embodiment, the electrodes 345 are current sensors disposed in an interior portion of the tank to facilitate exposure to the test fluid A. In another embodiment, each of the electrodes 345 may be a distributed sensor, such as a continuous conductor, which may be a plate, a wire, or a plurality of plates or wires, disposed around an outer portion of the tank 204 or around the wall of the tank 204. In another embodiment, each of the electrodes 345 may be a distributed array of current sensors each connected individually to the power supply 350 or to a current collector connected to the power supply 350.

The divider 234 extends from the floor of the tank 204 to a height less than a maximum height of the test fluid A in the tank 204. The divider 234 generally defines a plurality of test zones in the tank 204. By lowering the test fluid level to a height below the height of the divider 234, the tank 204 is divided into two test zones that may be operated independently. The divider 234 also provides additional support under a single substrate when operating the tank 204 as a test facility for single large substrates. In some embodiments, a single substrate being processed in the tank 204 may rest on an upper surface of the divider 234. The divider 234 may be formed integrally with the tank 204, or attached to the floor of the tank 204. If the tank 204 comprises molded plastic, the divider 234 may be formed as part of the molded shape of the tank 204. Alternately, the divider 234 may be attached to a plastic tank material using adhesive or by solvent or thermoplastic welding. In embodiments featuring continuous current sensors disposed along the tank wall 238, the sensor will also be disposed along the divider 234.

Use of a single divider 234 divides the tank 204 into two test zones. More test zones may be created by including more dividers in the tank. For example, use of two substantially parallel dividers may create three test zones in a tank. Appropriate extension of the support structure and sensor network would then enable simultaneous processing of three substrates. In another example, use of two dividers that intersect in a right angle will create up to four separate test zones. If the two dividers have different heights, the tank 204 may be divided into two test zones or four test zones to accommodate substrates of different sizes. It will be understood that placement of support structures, sensors, and connection pods may be adjusted to access the multiple test zones.

FIG. 3B is a plan view of the apparatus of FIG. 3A operated in dual mode. Two substrates, S₁ and S₂ are shown disposed in the tank 204. The junction box J₁ of the substrate S₁ is coupled to a peripheral connection pod 316, and the junction box J₂ of the substrate S₂ is coupled to another peripheral connection pod 316. The central connection pod 316 is unused in this embodiment. When the tank 204 operates in dual mode, each set of sensors 228, 230, 232, senses the test fluid of its local test zone to allow independent control of the properties in each test zone.

The tank 204 further comprises a plurality of sensors 228, 230, and 232, for sensing liquid level (228), temperature (230), and conductivity of the test fluid (232). As described above in connection with FIG. 2, these sensors may be used to control the overall electrical properties of the test fluid. When the tank 204 is used to process a single large substrate as in FIG. 3A, the two sets of sensors provide redundant readings that may be used to check the accuracy of the results. When the tank 204 is divided into two test zones by lowering the test fluid level, each set of sensors is used to control the properties of the test fluid in the respective test zones.

FIG. 3C is a top view of a substrate “S” connected to the apparatus of either FIG. 3A or FIG. 3B. The substrate “S” has a junction box “J” connected to a cross buss 356, which is in turn connected to one or more side busses 355, all of which are disposed within the substrate and connected to the individual solar cells that make up the substrate. The substrate “S” has a back glass panel 361 covering the cross buss 356 and side busses 355 to protect the electrical components of the substrate from environmental exposure. An edge exclusion zone 380 provides electrical isolation at the edges of the substrate. The junction box “J” has two connectors 371 electrically coupled to the cross buss 356. A connection pod 316 of the test apparatus is shown connecting with the connectors 371 of the junction box “J” through pins 375 inserted into the connectors 371. In some embodiments, each of the pins is actuated by a linear actuator, such as an air or pneumatic cylinder that operates to insert the pin into the connector when the connection pod 316 is positioned over the junction box “J”. In the embodiment of FIG. 3C, the connection pod 316 is shown as a box-like housing that fits over the junction box “J”, but in alternate embodiments, the connection pod 316 may comprise only the connection pins with alignment features to align the pins with the junction box “J”.

In operation, a solar cell substrate “S” is delivered to the apparatus 100 from a solar cell fabrication line using a conveyor that delivers the solar cell substrate S to the attachment apparatus 102. After a junction box “J” is attached to the substrate S, the conveyor 112 delivers the substrate S to the solar simulator 104 for solar flash testing. The conveyor 114 then delivers the substrate S to the high potential test apparatus 106. The automation assembly 201 receives the substrate S from the conveyor 114. The automation assembly 201 is positioned above the conveyor 114 when receiving the substrate S. After the substrate S is positioned on the automation assembly 201, the automation assembly 201 moves the substrate S into a test position in which the substrate S is substantially immersed in the test fluid A. The automation assembly 201 moves along the gantry 208 by virtue of an actuated motion assembly, such as the translators 314 of FIGS. 3A and 3B, that couples the automation assembly 201 to the gantry 208. The wet high potential test is generally performed by applying a high voltage to the electrical leads found in the junction box J disposed on the solar cell substrate S relative to the electrodes 345 to determine whether the portions of the active regions of the formed solar cell substrate S are sufficiently electrically isolated from the external environment. To complete the electrical circuit and assure that no low resistance paths exist within the solar cell substrate S, the testing is performed while the substrate S and electrodes 345 are both immersed in the test fluid A. Following the test, the automation assembly 201 lifts the substrate S out of the test fluid A, and delivers the substrate to an exit conveyor.

As shown in FIGS. 3A and 3B, the support frame 322 may extend beyond the tank 204 to engage with a substrate S waiting on a delivery conveyor 114. As the support frame 322 engages with the substrate S, by attachment vectors 312, the connection pod 316 automatically establishes electrical connection with the junction box J disposed on the substrate S, and the seals of the connection pod form liquid impermeable seals around the connectors. The support frame 322 moves the substrate S over the tank 204 and immerses the substrate S in the test fluid A held in the tank 204. As shown in the embodiment of FIG. 2, a liquid level 226 is maintained in the tank 204. In one embodiment, the substrate S is lowered into the test fluid A such that the fluid covers the laminate portions of the substrate S, with the junction box J remaining above the fluid level. The test fluid A is sprayed over the junction box by a pump and sprayer (not shown) coupled to the tank 204. Wetting the junction box ensures that any current leaking from features not immersed in the test liquid will be conducted into the fluid A and to the current sensor.

The rinse and dry station 306 of FIGS. 3A and 3B comprises a rinser 318 and a dryer 320. The rinser 318 may be a dispenser configured to to dispense a curtain of rinse fluid across the width of a substrate as it passes through the rinser 318. It should be noted that, in the plan view of FIGS. 3A and 3B, the rinser 318 is seen from above, but a component of the rinser 318 will generally also be located below the substrate path to contact both major surfaces of the substrate with rinse fluid. In other embodiments, the rinser 318 comprises a plurality of spray heads disposed above and below a conveyor passing through the rinser 318. In some embodiments, the spray heads may be actuated to distribute rinse fluid across a substrate surface. In still other embodiments, the rinser 318 may have a dispenser positioned proximate the substrate surface, near one edge thereof, for flowing rinse fluid across the substrate surface as it passes the dispenser.

The dryer 320 comprises a gas knife positioned to direct a stream of gas toward the substrate. The gas knife will generally apply a drying gas to both sides of the substrate, as with the rinser 318. The gas may be air, nitrogen, or another non-reactive gas, and the gas may be heated to facilitate drying. In one aspect, the gas stream physically removes fluid from the substrate by propelling the fluid from the substrate surface. In another aspect, the gas stream encourages evaporation of the rinse fluid from the substrate surface. The gas knife may be oriented to direct gas substantially perpendicular to the substrate surface, or at any desired angle.

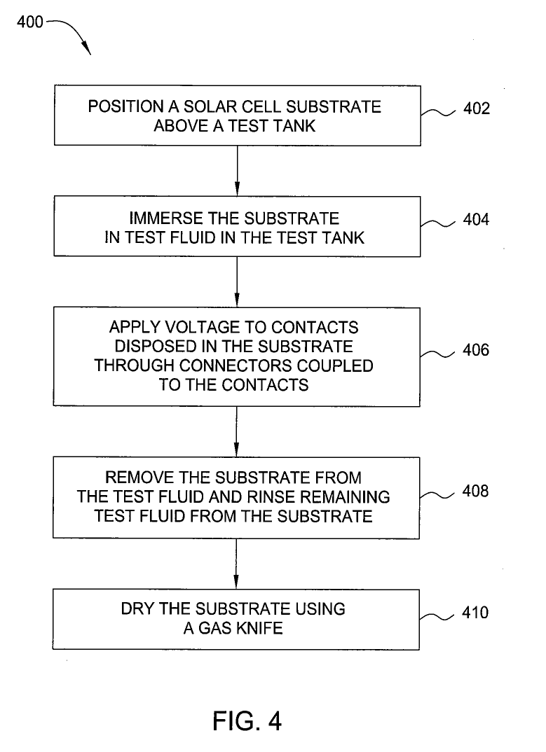

FIG. 4 is a flow diagram summarizing a test method 400 for a solar cell substrate according to one aspect. At 402, a solar cell substrate is positioned above a test tank. The substrate may be received from a factory interface, such as the conveyor 114, and positioned above a test tank by a carrier, such as the automation assembly 201. At 404, the substrate is immersed in a test fluid in the test tank. The test fluid is generally conductive to facilitate detecting any electrical current arising from dielectric breakthrough and/or unwanted air bubbles in the laminated solar cell structure of the solar cell substrate. The solar cell substrate is generally immersed in the test fluid in a way that preserves access to electrical contacts disposed in the substrate, so that a test voltage may be applied to the contacts. In many solar cell substrates, the contacts are collected in a junction box to facilitate connections to outside circuits. In some embodiments, the connection with the electrical contacts in the junction box is sealed to prevent liquid intrusion.

At 406, a test voltage is applied to the contacts. The test voltage is applied by ramping the voltage up from 0 to a target voltage. The target voltage is determined by the amount of dielectric resistance the substrate is designed to provide and the desired signal current for detecting breakthrough. In some embodiments, the signal current will be between about 10 μA and about 70 μA. A sensor is disposed in the test fluid to detect any current leaking from the solar cell substrate. Should there be a defect in the substrate, current will flow from the conductors disposed within the substrate, through the dielectric flaw into the conductive liquid, which will conduct the current to the sensor.

At 408, the substrate is removed from the test tank and maneuvered into a cleaning apparatus. The test fluid is generally rinsed off the substrate using a water spray, or another appropriate rinse fluid, such as an aqueous or organic solvent or some mixture thereof, which may be delivered to the top and bottom of the substrate simultaneously. At 410, the substrate is then dried using a gas knife. The gas knife directs air, or another drying gas such as nitrogen, against the substrate in a thin, high-velocity sheet to evaporate and physically remove liquid from the substrate. In some embodiments, the gas knife may be configured to apply the air sheet to the substrate at an angle to enhance removal of liquid.

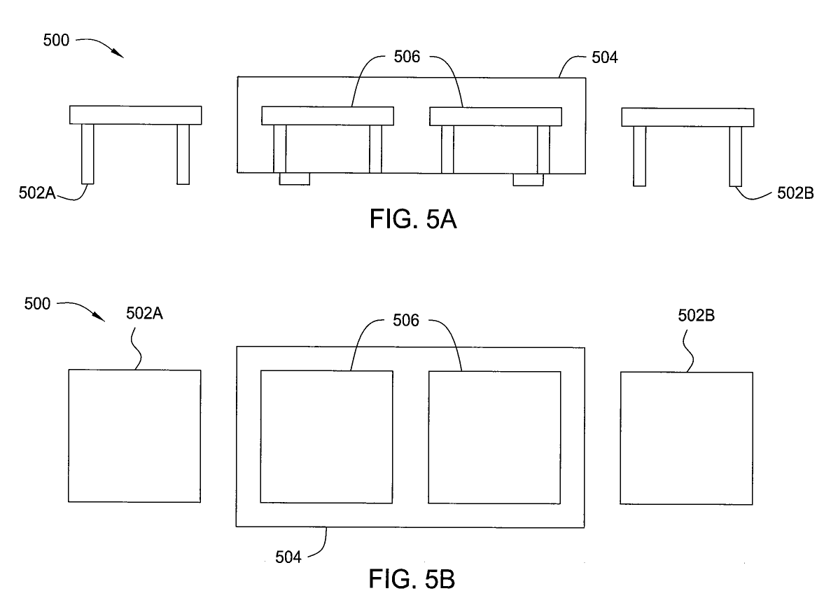

FIG. 5A is a schematic side-view of a wet high potential test apparatus 500 according to another embodiment. FIG. 5B is a top view of the apparatus 500 of FIG. 5A. The wet high potential test apparatus 500 in the embodiment of FIGS. 5A and 5B comprises at least two delivery conveyors 502A/B and a test tank 504. The test tank 504 comprises at least two test stations 506. Each of the two test stations 506 is configured to support a solar cell substrate in a test position inside the test tank 506 for simultaneous, overlapping, or non-overlapping testing of multiple substrates. A single substrate handler or lift mechanism such as those described above may be used to manipulate two substrates into test positions on the test stations 506 independently, or a substrate handler may be dedicated to each test station.

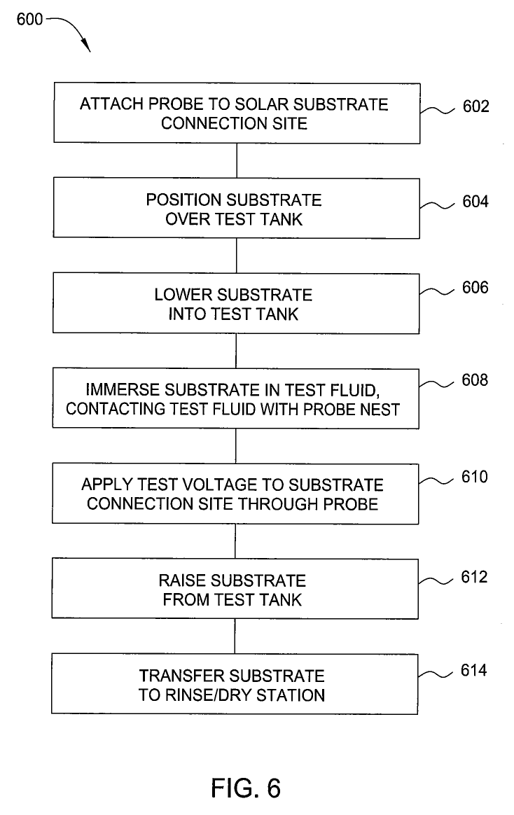

FIG. 6 is a flow diagram summarizing a method 600 according to another embodiment. The method 600 is similar in many respects to the method 400 of FIG. 4, and is similarly useful for measuring the electrical integrity of a solar cell device. At 602, a probe is attached to a connection site of a solar cell substrate. The probe may resemble any of the embodiments described elsewhere herein, or any other convenient embodiment. For example, the probe may have a probe nest of connectors that makes an electrical connection to the solar cell substrate through the connection site, placing a power supply coupled to the probe in electrical communication with conductors disposed inside the solar cell substrate.

At 604, the solar cell substrate is positioned over a test tank for performing a wet high potential test, such as any of the embodiments described elsewhere herein, or any other convenient embodiment of test enclosure. Instead of a tank, a test tray may be used in some embodiments. Positioning may be accomplished through any convenient means, such as proximity switches coupled to linear actuators that move the substrate connected to the probe.

At 606, the substrate is lowered into the test tank. The tank contains a test fluid that provides a conductive medium for detecting current leakage from the solar cell substrate when a high voltage is applied to the connection site. The test fluid may be an aqueous surfactant solution in some embodiments. The substrate is immersed in the test fluid at 608, such that the test fluid contacts the probe nest. This ensures that any current leakage from any part of the solar cell substrate is conducted through the test medium to current sensors disposed in the test tank.

At 610, a test voltage is applied to the substrate connection site through the probe. Current will leak through any structural dislocations, such as air bubbles or impurities, in the material of the solar cell substrate, and will emerge into the test fluid. The test fluid conducts the fugitive current to sensors disposed in the test tank. Generally, at least about 500 V is applied to the substrate, or in some embodiments at least 1,000 V, depending on the size and rated voltage of the substrate. Detected current greater than about 40 mA generally indicates unacceptable leakage.

At 612, the substrate is raised out of the test tank, and at 614, the substrate is transferred to a rinse/dry station, where a cleaning fluid is applied to remove any remaining test fluid, and a gas knife dries the substrate.

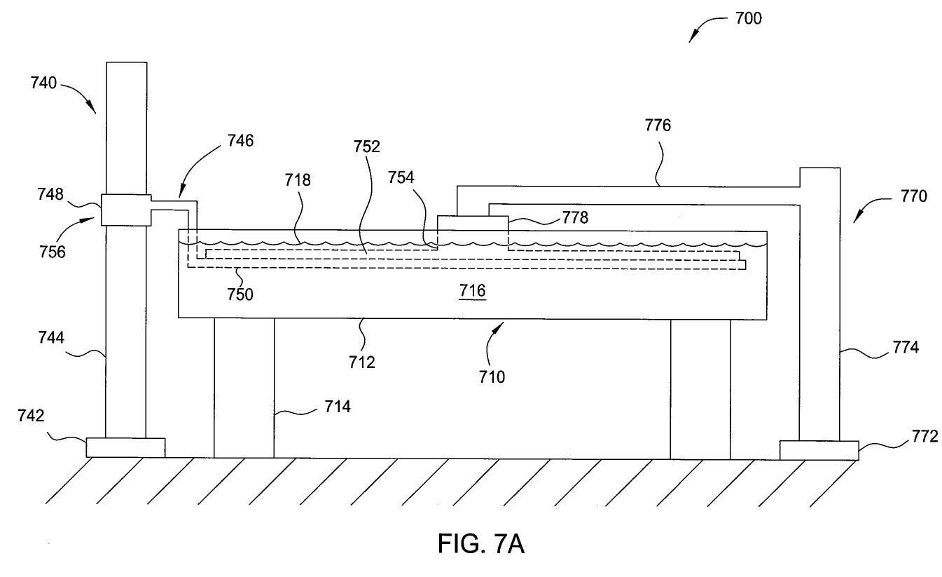

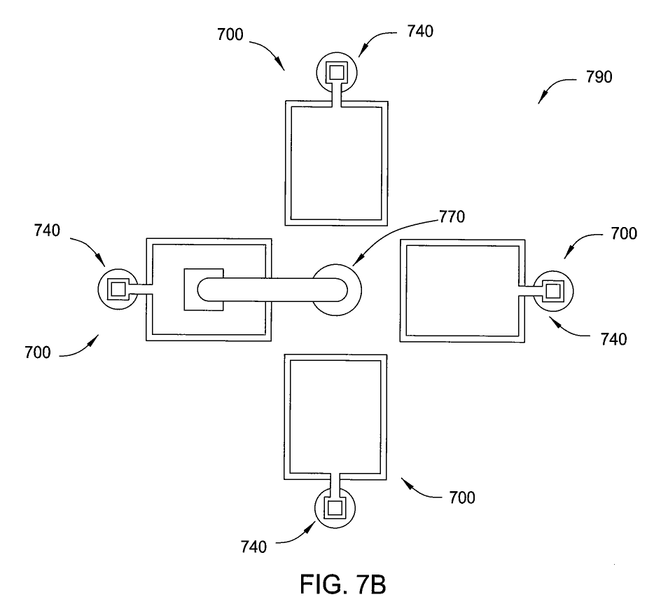

FIG. 7A is a schematic side view of a wet high-potential test apparatus 700 according to another embodiment. The apparatus 700 comprises a test station 710, a lift assembly 740, and a probe assembly 770. The test station 710 comprises a test enclosure 716, which may be a tank, tray, or vat, disposed on a plurality of supports 714. The enclosure 716 contains a test fluid 718, similar to those described elsewhere herein.

The lift assembly 740 of FIG. 7A comprises a base 742 and a lift support member 744, which provides a basis for movement of a lift member 756 along the lift support member 744. The lift member 756 comprises a support coupling 748 attached to an arm 746, and a substrate support surface 750 connected to the arm 746. The support coupling 748 is actuated to move along the lift support member 744, thus moving the substrate support surface 750 into and out of the test enclosure 716. A substrate 752, having a connection site 754, such as a junction box, moves with the substrate support surface 750 into and out of the test enclosure 716, and the test fluid 718 disposed therein.

The substrate support surface 750 may be a conveyor in some embodiments. In the embodiment of FIG. 7A, the substrate support surface 750 may be a conveyor configured to move a substrate in a direction substantially perpendicular to the direction of movement of the lift member 756. A feed conveyor may position a substrate such that an edge of the substrate contacts the substrate support surface 750. Operation of the conveyor may then move the substrate from the feed conveyor onto the substrate support surface 750 in preparation for immersion in the test tank 716. Following the test, the conveyor associated with the substrate support surface 750 will deliver the substrate to a subsequent processing station.

The probe assembly 770 comprises a base 772, a probe support member 774, an extension arm 776, and a probe nest 778. The probe assembly 770 positions the probe nest 778 to contact the connection site 754 of the substrate, making an electrical connection between one or more probes in the probe nest 778 and conductors disposed within the substrate. The extension arm 776, probe support member 774, and probe nest 778 may each, or all, be actuated to position the probe nest 778 for connecting to the connection site 754.

The probe assembly 770 and the lift assembly 740 may be rotationally actuated as well. One of both of the lift support member 744 and the probe support member 774 may be rotatably coupled to their respective bases 742 and 772. A rotational coupling would enable the lift support member 756 to rotate from a position proximate to the test enclosure 716 to a position away from the test enclosure for collecting and delivering substrates to and from other processing equipment. A rotational coupling would likewise enable the probe support member 774 to function with more than one test enclosure 716 by rotating among a plurality of test stations. FIG. 7B is a plan view showing an embodiment of a multi-station test facility 790. The probe assembly 770, rotatably coupled to its base as described above, is disposed in a central location among a plurality of the test apparatus 700. Each test apparatus 700 may be fed by a conveyor (not shown), which may be located conveniently proximate the lift assembly 740 of each test apparatus 700. Each lift assembly 740, rotatably coupled to its base as described above, may rotate to collect and deliver substrates to and from the feed conveyors, and to dispose the substrates in the test enclosure of each test apparatus 700. Although the embodiment of FIG. 7B features four test apparatus 700 for a single probe assembly 770, any convenient number of test apparatus 700 may be grouped around a single probe assembly 770, limited only by the rate at which substrates may be processed through a test enclosure. It should be noted that the test enclosures grouped around a probe assembly may be of different dimensions in some embodiments to accommodate testing substrates of different sizes.

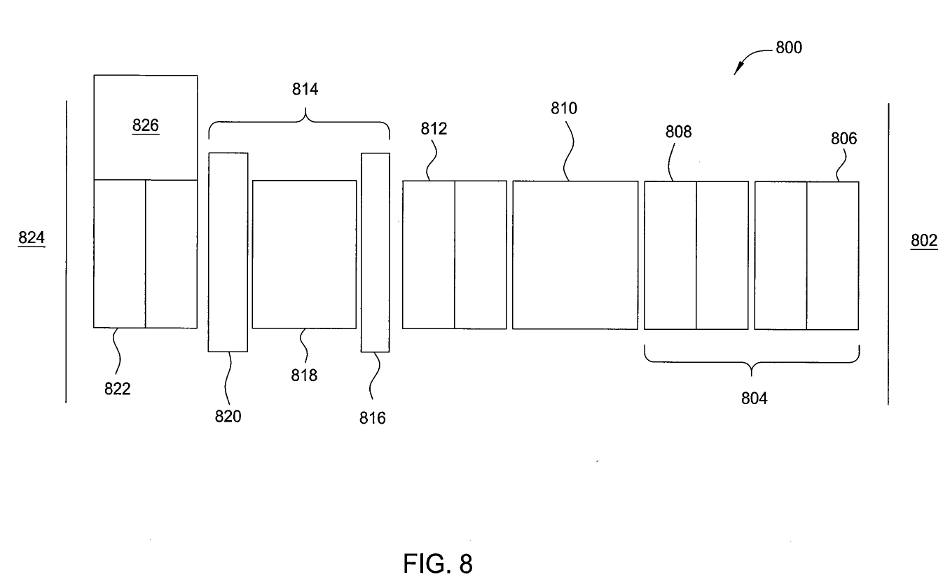

FIG. 8 is a schematic plan view of a test facility 800 according to another embodiment. The test facility 800 is similar in many respects to the apparatus 100 of FIG. 1, and may be used to perform wet high-potential testing of solar cell substrates. A feed conveyor assembly 804 collects substrates from a processing line 802, and delivers them to a test station 810. The feed conveyor assembly 804 may comprise a plurality of conveyors, such as a first conveyor 806 and a second conveyor 808 as in FIG. 8, for various purposes. For example the first conveyor 806 may be a pickup conveyor that collects substrates from the processing line 802, while the second conveyor 808 is a feed-in conveyor that can collect substrates from the pickup conveyor 806 or from another processing line (not shown) and feed them into the test station 810. The test station 810 may be any of the test station embodiments described herein, or any convenient permutation of an embodiment described herein. A finish conveyor 812 delivers substrates from the test station 810 to the clean station 814, which comprises a rinser 818 and a dryer 820, as described elsewhere herein, and may also contain a blower 816 to remove excess test fluid from substrates, which may be recycled to the test station 810. Clean dry substrates that pass the high-potential test administered at the test station 810 are delivered to the processing line 824 by the exit conveyor 822. Those that do not pass may be delivered to a scrap bin 826, if desired, by the same exit conveyor 822.

While the foregoing is directed to embodiments of the invention, other and further embodiments of the invention may be devised without departing from the basic scope thereof.

What is claimed is:

1. An apparatus for processing a solar cell substrate, comprising:
a test apparatus, comprising:
a test fluid enclosure;
an electrical sensor disposed in the test fluid enclosure; and
a substrate support having a frame for handling a substrate, a connection pod for making electrical connection with connectors disposed within the substrate, and a motion assembly for positioning the substrate.

2. The apparatus of claim 1, further comprising:
a cleaning apparatus, comprising:
a rinse station configured to spray a rinsing fluid on two surfaces of the substrate; and
a gas knife for removing liquid from the substrate.

3. The apparatus of claim 1, wherein the electrical sensor is a conductivity probe positioned to contact a test fluid contained in the test fluid enclosure.

4. The apparatus of claim 1, wherein the frame comprises a plurality of vacuum attachment vectors.

5. The apparatus of claim 1, wherein the connection pod comprises a liquid impermeable seal.

6. The apparatus of claim 1, further comprising a temperature sensor, level sensor, and conductivity sensor disposed in the test fluid enclosure.

7. The apparatus of claim 1, wherein the electrical sensor and the connection pod are each connected to a power supply.

8. The apparatus of claim 7, wherein the power supply is configured to deliver electrical power to the connection pod.

9. A test apparatus for a solar cell manufacturing line, comprising:
an entry conveyor for transporting solar cell substrates from the solar cell manufacturing line to the test apparatus;
an attachment device for attaching a junction box to the solar cell substrate;
a solar simulator configured to flash solar spectrum radiation and sense electric current produced by the solar cell substrate; and
a high potential tester, comprising:
a test fluid enclosure for containing an electrolyte test fluid;
an electrical sensor disposed in the test fluid enclosure;
a substrate handler configured to engage with the substrate and dispose the substrate in the electrolyte test fluid, the substrate handler comprising a connection pod configured to make electrical connection with the junction box;
a power supply connected to the connection pod and the electrical sensor;
a rinse dry station; and
an exit conveyor for delivering substrates from the test apparatus to the solar cell manufacturing line.

10. The apparatus of claim 9, further comprising a temperature sensor, a level sensor, and a conductivity sensor disposed in the test fluid enclosure.

11. The apparatus of claim 9, wherein the electrical sensor is a conductivity probe disposed in the test fluid.

12. The apparatus of claim 9, wherein the test fluid enclosure comprises plastic.

13. The apparatus of claim 9, wherein the test fluid enclosure comprises a divider defining a plurality of separated test zones.

14. The apparatus of claim 9, wherein the substrate handler comprises a solar cell connection pod coupled to a vertical motion assembly, and the substrate handler is coupled to a gantry by a horizontal motion assembly.

15. The apparatus of claim 14, wherein the gantry extends above the entry conveyor.

16. A method of processing a solar cell substrate, comprising:
disposing the substrate in a test fluid;
applying a voltage to contacts disposed within the substrate;
sensing electric current emerging from an edge of the substrate into the test fluid using a current sensor immersed in the test fluid;
removing the substrate from the test fluid;
rinsing the test fluid from the substrate; and
drying the substrate using a gas knife.

17. The method of claim 16, wherein sensing electric current emerging from an edge of the substrate into the test fluid comprises disposing an electric sensor in the test fluid and connecting a power supply to the contacts disposed within the substrate and to the electric sensor.

18. The method of claim 17, wherein rinsing the test fluid from the substrate comprises directing multiple streams of a rinse fluid toward at least two surfaces of the substrate simultaneously.

19. The method of claim 18, wherein the gas knife comprises at least two angled gas blades directed toward at least two surfaces of the substrate.

20. The method of claim 16, wherein the test fluid is electrically conductive.

21. The method of claim 20, wherein the test fluid is a surfactant solution or an electrolyte solution.

22. The method of claim 18, further comprising controlling the conductivity of the test fluid by adding an electrolyte to the test fluid, and controlling the quantity of test fluid by adding a solvent to the test fluid.
